(19) United States
(12) Patent Application Publication
(10) Pub. No.: US 2026/0182291 A1
(43) Pub. Date: Jun. 25, 2026

(54) HIGH PRESSSURE SUBSTRATE PROCESSING APPARATUS AND GASEOUS HYDROGEN OXIDE GENERATING MODULE

(71) Applicant: HPSP Co., Ltd., Hwaseong-si (KR)

(72) Inventors: Dong Min KIM, Hwaseong-si (KR); Se Chang OH, Hwaseong-si (KR); Hye Seong YOON, Hwaseong-si (KR); Si Hyung LEE, Hwaseong-si (KR); Manuel Scott RIVERA, Sunnyvale, CA (US); Jose Salvador COTO, Sunnyvale, CA (US)

(21) Appl. No.: 18/999,642

(22) Filed: Dec. 23, 2024

(51) Int. Cl. H01L 21/67; B01B 1/00

(52) U.S. Cl. CPC H10P 72/0402; B01B 1/005

(57) ABSTRACT

Disclosed are a high pressure substrate processing apparatus and a gaseous hydrogen oxide generating module. The apparatus includes an internal chamber, a generating module, and a control module. The internal chamber includes a processing area accommodating a processing gas including gaseous hydrogen oxide and having a processing pressure higher than atmospheric pressure and accommodating a substrate to be processed using the processing gas. The generating module includes a generating chamber and a heating unit. The generating chamber is made of a soluble material and includes a generating area accommodating a raw fluid while communicating with the processing area. The heating unit is configured to heat the raw fluid accommodated in the generating area to generate the gaseous hydrogen oxide. The control module is configured to control the operation of the heating unit to provide the generating area with an amount of heat that generates the gaseous hydrogen oxide without generating liquid hydrogen oxide from the raw fluid.

### BACKGROUND

### Field

The present disclosure relates to a high pressure substrate processing apparatus and a gaseous hydrogen oxide generating module.

### Description of the Related Art

In general, various processing may be performed on a semiconductor substrate during a manufacturing process of a semiconductor device. An example of the processing may include oxidation, nitriding, ion implantation, deposition, or the like. The example may also include a hydrogen or deuterium heat treatment process to improve an interface property of the semiconductor device.

The process may be broadly classified into a vacuum process and a high-pressure process based on a pressure of a gas acting on the substrate. If the former is performed at a pressure lower than atmospheric pressure, the latter is performed at a pressure higher than the atmospheric pressure.

These two processes have different characteristics and features, and what is not a problem in one process may thus cause a significant problem in the other process. For example, when using water vapor in wet oxidation, an impurity may be a serious problem in the high-pressure process, unlike in the vacuum process.

### SUMMARY

The present inventor recognizes that an impurity may enter from outside a chamber where a process is performed and may also be formed inside the chamber. For example, a material forming the chamber of a water vapor generating module may become the impurity as the chamber is dissolved. The chamber may also allow the impurity to be formed as the chamber is oxidized upon contact with water vapor or the like. The impurity may act on a substrate and cause a defect in the substrate.

An object of the present disclosure is to provide a high pressure substrate processing apparatus which may minimize the formation of foreign materials in a gas-generating chamber, and a gaseous hydrogen oxide generating module.

According to an embodiment of the present disclosure, provided is a high pressure substrate processing apparatus including: an internal chamber including a processing area accommodating a processing gas including gaseous hydrogen oxide and having a processing pressure higher than atmospheric pressure and accommodating a substrate to be processed using the processing gas; a generating module including a generating chamber made of a soluble material and including a generating area accommodating a raw fluid while communicating with the processing area, and a heating unit configured to heat the raw fluid accommodated in the generating area to generate the gaseous hydrogen oxide; and a control module configured to control the operation of the heating unit to provide the generating area with an amount of heat that generates the gaseous hydrogen oxide without generating liquid hydrogen oxide from the raw fluid.

The control module may be configured to control the operation of the heating unit to allow a temperature in the generating area to be higher than a critical temperature of the gaseous hydrogen oxide.

The internal chamber may further include a wafer boat made of silicon carbide and configured to stack the substrate thereon.

The apparatus may further include: an external chamber including a protective area accommodating the internal chamber and a protective gas having a protective pressure set in relation to the processing pressure; and a fluid supply module configured to supply the raw fluid to the generating area and the protective gas to the protective area, wherein the control module is configured to control the operation of the fluid supply module to supply the raw fluid to the generating area at a pressure higher than the atmospheric pressure.

The generating chamber may be disposed in an atmosphere of the protective gas, and the control module may be configured to control the operation of the fluid supply module to regulate supply amounts of the raw fluid and the protective gas for the processing pressure and the protective pressure to have a set relationship.

The generating chamber may be disposed in the protective area.

The generating chamber may be disposed outside the external chamber, and the generating module may further include a casing chamber accommodating the generating chamber; and a communication line communicating the casing chamber to the protective area.

The generating module may further include a casing chamber accommodating the generating chamber and the heating unit

The casing chamber may be configured to communicate with the protective area to expose the generating chamber to the protective pressure.

The soluble material may include silica.

The raw material fluid may include hydrogen gas and oxygen gas.

According to another embodiment of the present disclosure, provided is a gaseous hydrogen oxide generating module including: a generating chamber made of a soluble material in a first temperature range and including a generating area accommodating a raw material fluid; and a heating unit configured to heat the generating area to generate gaseous hydrogen oxide from the raw material fluid in a second temperature range different from the first temperature range.

The second temperature range may be set to a temperature higher than a critical temperature of the gaseous hydrogen oxide.

According to yet another embodiment of the present disclosure, provided is a high pressure substrate processing apparatus including: an internal chamber including a processing area accommodating a processing gas including gaseous hydrogen oxide and having a processing pressure higher than atmospheric pressure and accommodating a substrate to be processed using the processing gas; and a generating module including a generating chamber having a generating area accommodating a raw fluid while communicating with the processing area, a reinforced coating layer disposed in an interior of the generating chamber defining the generating area, and a heating unit configured to heat the raw fluid in contact with the reinforced coating layer to generate the gaseous hydrogen oxide.

The generating chamber may be made of one of a metal and a soluble material, and the reinforced coating layer may include a plating layer.

The plating layer may be made of at least one of gold, silver, and nickel.

The plating layer may include a first plating layer made of a first metal, and a second plating layer made of a second metal, different from the first metal, and disposed on the first plating layer.

The plating layer may further include a third plating layer disposed between the interior and the first plating layer.

The third plating layer may be made of the same metal as the first metal and be thinner than the first plating layer.

The generating chamber may be made of one of a metal and a soluble material, and the reinforced coating layer may include a polymer layer.

The polymer layer may be made of amorphous silicon oxide.

The apparatus may further include an external chamber including a protective area accommodating the internal chamber and a protective gas having a protective pressure set in relation to the processing pressure, wherein the generating chamber is disposed in the protective area to be exposed to the protective pressure.

The raw fluid may include liquid hydrogen oxide.

According to still another embodiment of the present disclosure, provided is a gaseous hydrogen oxide generating module including: a generating chamber including a generating area accommodating a raw fluid; a reinforced coating layer disposed in an interior of the generating chamber defining the generating area; and a heating unit configured to heat the raw fluid in contact with the reinforced coating layer to generate gaseous hydrogen oxide.

The generating chamber may be made of one of a metal and a soluble material, and the reinforced coating layer may include a plating layer.

The plating layer may include a first plating layer made of a first metal, and a second plating layer made of a second metal, different from the first metal, and disposed on the first plating layer.

The generating chamber may be made of one of a metal and a soluble material, and the reinforced coating layer may include a polymer layer made of amorphous silicon oxide.

### BRIEF DESCRIPTION OF THE DRAWINGS

FIG. 1 is a conceptual diagram of a high pressure substrate processing apparatus according to an embodiment.

FIG. 2 is a block diagram for describing a control operation of the high pressure substrate processing apparatus shown in FIG. 1.

FIG. 3 is a cross-sectional view showing a generating module in FIG. 2.

FIG. 4 is a graph showing an amount of dissolved silica according to temperature.

FIG. 5 is a cross-sectional view showing a generating module according to a modified example of FIG. 3.

FIG. 6 is a cross-sectional view showing a generating module according to another modified example of FIG. 3.

FIG. 7 is a cross-sectional view showing a generating module according to another embodiment.

FIG. 8 is an enlarged cross-sectional view showing a portion of FIG. 7.

FIG. 9 is a cross-sectional view showing a generating module according to a modified example of FIG. 8.

FIG. 10 is a cross-sectional view showing a generating module according to another modified example of FIG. 8.

### DETAILED DESCRIPTION

Hereinafter, embodiments of the present disclosure are described in detail with reference to the accompanying drawings.

The present disclosure is not limited to the embodiments described below, may be variously modified, and may be implemented in various forms. These embodiments are provided only to make the present disclosure complete and allow those skilled in the art to completely appreciate the scope of the present disclosure. Therefore, it should be understood that the present disclosure is not limited to the embodiments disclosed below, and includes substitution or addition of a configuration in one embodiment with or to a configuration in another embodiment, as well as all modifications, equivalents, or substitutions, included in the spirit and scope of the present disclosure.

It should be understood that the accompanying drawings are provided only to allow the embodiments of the present disclosure to be easily understood, and the spirit of the present disclosure is not limited to the accompanying drawings and includes all the modifications, equivalents and substitutions included in the spirit and scope of the present disclosure. In consideration of convenience of understanding, the size or thickness of a component may be exaggeratedly expressed as larger or smaller in the drawings. However, the scope of the present disclosure should not be interpreted as being limited by this expression.

Terms used in the specification are used only to describe the specific implementation examples or embodiments rather than limiting the present disclosure. Here, a term of a singular number includes its plural number unless explicitly interpreted otherwise in the context. Terms “include”, “have”, and the like used in the specification specify the presence of features, numerals, steps, operations, components, parts, or combinations thereof, mentioned in the specification. That is, it should be understood that the term “include” or “have” does not preclude the presence or addition of one or more other features, numerals, operations, components, parts, or combinations thereof, which is mentioned in the specification.

Terms including ordinal numbers such as “first” and “second” may be used to describe various components. However, these components are not constrained by these terms. These terms are used only to distinguish one component and another component from each other.

It should be understood that when one element is referred to as being “connected/communicated to” or “in contact with” another element, one element may be directly connected/communicated to or in direct contact with another element, or may be connected/communicated to or in contact with another element while having a third element interposed therebetween. On the other hand, it should be understood that when one component is referred to as being “directly connected to” or “directly coupled to” another component, one component may be connected or coupled to another component without a third component interposed therebetween.

It should be understood that when a component is referred to as being “on” or “below” another component, the component may be “directly on” another component, or may have a third component interposed therebetween.

Unless defined otherwise, it should be understood that all the terms including technical and scientific terms used herein have the same meanings as those generally understood by those skilled in the art to which the present disclosure pertains. Such terms as those defined in a generally used dictionary should be interpreted as having meanings equal to the contextual meanings in the relevant field of art, and should not be interpreted as having ideal or excessively formal meanings unless clearly defined as such in the present application.

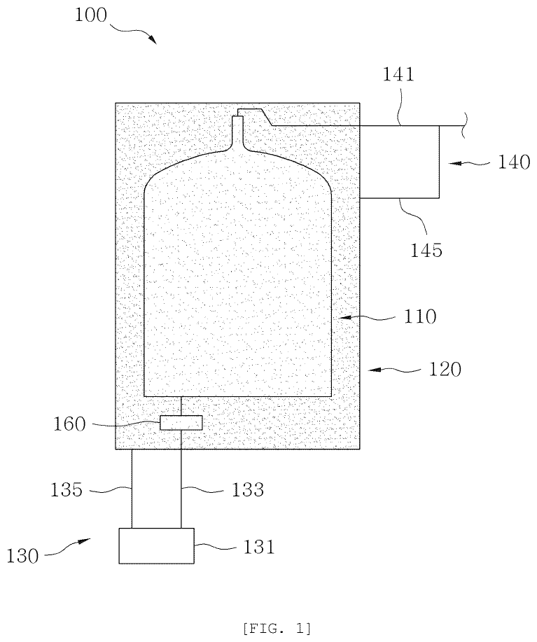

FIG. 1 is a conceptual diagram of a high pressure substrate processing apparatus according to an embodiment.

Referring to this drawing, a high pressure substrate processing apparatus 100 may include an internal chamber 110, an external chamber 120, a fluid supply module 130, a gas exhaust module 140, and a generating module 160.

The internal chamber 110 may include a processing area accommodating a substrate to be processed. The internal chamber 110 may be made of a non-metallic material, such as quartz, to reduce contamination in a high temperature and high pressure working environment. Although simplified in the drawing, a door (not shown) for opening and closing the processing area may be disposed at the bottom of the internal chamber 110. As the door is lowered, the processing area may be opened and the substrate may be fed into the processing area. The substrate may be, for example, a wafer for semiconductor manufacturing. The wafer may have/include a material such as silicon (Si), silicon carbide (SiC), gallium nitride (GaN), or the like. The substrate is not limited to the wafer, and may be any other base structure for making a circuit. For example, the substrate may also include glass for manufacturing a display. A holder may be a boat which may stack the substrates in a plurality of layers. The above boat may be made of an insoluble material, for example, silicon carbide (SiC). As a heater (not shown) disposed outside the internal chamber 110 is operated, a temperature in the internal chamber 110 may reach hundreds to thousands of degrees Celsius.

The external chamber 120 may include a protective area accommodating the internal chamber 110. Unlike the internal chamber 110, the external chamber 120 is free from a concern about contamination of the substrate, and may thus be made of a metal material. The external chamber 120 may also have a door (not shown) disposed at the bottom, and this door (external door) may be lowered together with the door (internal door) of the internal chamber 110 and may open the protective area. The internal chamber 120 may be installed in the external chamber 110.

The fluid supply module 130 is a component for supplying a fluid to the internal chamber 110 and the external chamber 120. The fluid supply module 130 may include a fluid supplier 131 communicating with a utility (fluid supply facility) of a substrate processing plant. The fluid supplier 131 may selectively provide the processing area with a processing gas, such as hydrogen gas (H₂), deuterium gas (D₂), gaseous hydrogen oxide, fluorine gas (F₂), ammonia gas (NH₃), chlorine gas (Cl₂), or nitrogen gas (N₂). The gaseous hydrogen oxide may be generated by the generating module 160 (i.e., gaseous hydrogen oxide generating module) described below and supplied to the processing area. In this case, the fluid supply module 130 may provide the generating module 160 with a raw fluid for generating the gaseous hydrogen oxide. The gaseous hydrogen oxide may be used for wet oxidation, atomic layer deposition (ALD), chemical vapor deposition (CVD), heat treatment (annealing), or the like. The fluid supplier 131 may provide the protective area with a protective gas, for example, an inert gas such as nitrogen gas or argon gas (Ar). The processing gas and the protective gas may be simply referred to as a process gas. The process gas may be supplied to the processing area or the protective area through a processing gas line 133 or a protective gas line 135. The protective gas supplied to the protective area may be specifically supplied to the remaining space (protective space) excluding a space occupied by the internal chamber 110 among the external chamber 120.

The process gas may be supplied to the chambers 110 and 120 to form a pressure (high pressure) higher than atmospheric pressure, for example, from several atmospheres to several tens of atmospheres, or even more. A processing pressure, which is a pressure of the processing gas in the internal chamber 110, and a protective pressure, which is a pressure of the protective gas in the external chamber 120, may be maintained in a set relationship. For example, the protective pressure may be set to be substantially the same as or slightly greater than the processing pressure. Such a pressure relationship may prevent leakage of the processing gas from the internal chamber 110 and breakage of the internal chamber 110. The protective pressure may be set to be slightly lower than the processing pressure, and a similar effect as before may be achieved even in that case.

The gas exhaust module 140 is a component for exhausting the process gas. In order to exhaust the processing gas from the internal chamber 110, a gas exhaust line 141 may be connected to the top of the internal chamber 110. Similarly, a gas exhaust line 145 connected to the external chamber 120 may be provided to exhaust the protective gas from the external chamber 120. These gas exhaust lines 141 and 145 may be combined into one, and the processing gas may thus be diluted with the protective gas during the exhaust process to have a lower concentration.

The generating module 160 is a component for generating hydrogen oxide. The hydrogen oxide is a molecule composed of oxygen and hydrogen, and may include at least one of hydrogen oxide (H₂O), hydrogen peroxide (H₂O₂), and trioxidane (H₂O₃). The hydrogen oxide may basically be the above-mentioned gaseous hydrogen oxide. The generating module 160 may be operated in conjunction with the fluid supply module 130. In detail, the generating module 160 may be installed on the processing gas line 133 or may be installed to communicate with the processing gas line 133. The generating module 160 may also communicate with the processing area. Accordingly, the gaseous hydrogen oxide may be supplied to the processing area and may form a part of the processing gas. In an alternative embodiment, the processing gas line 133 may include a line on which the generating module 160 is installed and a line on which the generating module 160 is not installed. The latter may be used to supply the processing area with a gas other than the gaseous hydrogen oxide.

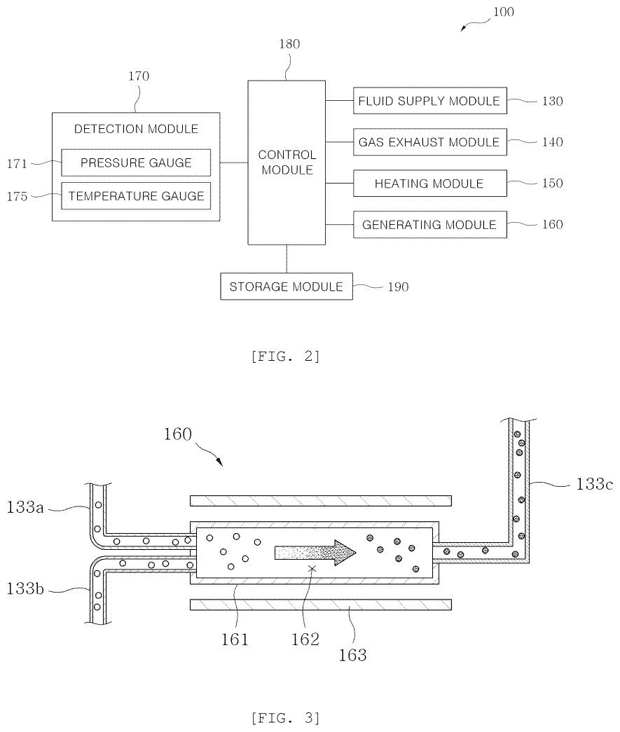

A control configuration of the high pressure substrate processing apparatus 100 is described with reference to FIG. 2. FIG. 2 is a block diagram for describing a control operation of the high pressure substrate processing apparatus shown in FIG. 1.

Referring to this drawing (and FIG. 1), the high pressure substrate processing apparatus 100 may further include a heating module 150, a detection module 170, a control module 180, and a storage module 190 in addition to the fluid supply module 130 and the gas exhaust module 140 described above.

The heating module 150 may include the above-mentioned heater. The heater may face the internal chamber 110 within the external chamber 120.

The detection module 170 is a component for detecting environments of the chambers 110 and 120, and further, the generating module 160. The detection module 170 may include a pressure gauge 171 and a temperature gauge 175. The pressure gauge 171 and the temperature gauge 175 may be installed in the chambers 110 and 120, further in the generating module 160, or in a part communicated with the generating module 160 (e.g., processing gas line 133). The detection module 170 may also include a gas detection device (not shown) for detecting the presence of a specific gas.

The control module 180 is a component for controlling the fluid supply module 130 and the gas exhaust module 140. The control module 180 may control an operation of the fluid supply module 130 or the like based on a detection result of the detection module 170.

The storage module 190 is a component for storing data, programs, or the like that may be referred to control the control module 180.

According to this configuration, the control module 180 may control the fluid supply module 130 and the generating module 160 based on the pressure in the chamber 110 or 120 or the generating module 160 acquired using the pressure gauge 171. The processing gas may cause the processing area to have the processing pressure based on the operation of the fluid supply module 130 or the generating module 160. The protective space may be filled with the protective gas at the protective pressure.

The control module 180 may also control the operation of the gas exhaust module 140 based on the pressure in the chamber 110 or 120 or the generating module 160 acquired using the pressure gauge 171. The processing gas may be exhausted from the processing area based on the operation of the gas exhaust module 140. The protective gas may be exhausted from the protective space.

The control module 180 may control the operation of the heating module 150 based on temperatures in the chambers 110 and 120 acquired using the temperature gauge 175. The processing gas may reach a processing temperature for processing the substrate based on the operation of the heating module 150.

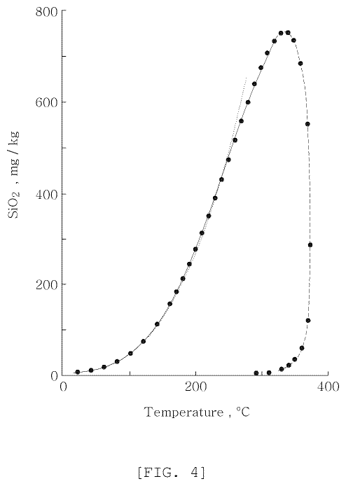

The control module 180 may also control the operations of the generating module 160 and the fluid supply module 130 to allow the generating module 160 to generate the gaseous hydrogen oxide at a set temperature and pressure. This configuration is described with reference to FIGS. 3 and 4.

FIG. 3 is a cross-sectional view showing the generating module in FIG. 2, and FIG. 4 is a graph showing an amount of dissolved silica based on a temperature.

Referring to FIG. 3, the generating module 160 may include a generating chamber 161 and a heating unit 163.

The generating chamber 161 may be disposed in an atmosphere of the protective gas. In detail, the generating chamber 161 may be disposed in the protective area.

The generating chamber 161 may have a generating area 162 as its internal space. A hydrogen line 133a and an oxygen line 133b may be connected to the generating area 162. The hydrogen line 133a and the oxygen line 133b may be connected to the fluid supplier 131 (see FIG. 1), and the generating area 162 may receive the hydrogen gas and the oxygen gas (raw fluid) through the lines 133a and 133b. The generating area 162 may also communicate with the processing area through an input line 133c. As the generating area 162 communicates with the processing area, the gaseous hydrogen oxide generated in the generating area 162 may be supplied to the processing area. In addition, the pressure in the generating area 162 (mainly due to the hydrogen oxide) may be substantially the same as the processing pressure. The hydrogen gas and the oxygen gas may react in the generating area 162 to generate the hydrogen oxide. The generating chamber 161 may be made of a material made of silica (SiO₂) that is resistant to contamination, for example, quartz. However, the silica is a soluble material under a certain condition.

The heating unit 163 is a component for generating heat for a temperature in the generating area 162 to reach the set temperature. The heating unit 163 may be disposed outside the generating chamber 161 and surround the generating chamber 161. Heat generated by the heating unit 163 may pass through the generating chamber 161 made of the quartz material to heat the hydrogen gas and the oxygen gas. The hydrogen gas and the oxygen gas may generate the hydrogen oxide in a heated atmosphere.

Liquid hydrogen oxide in a liquid state may dissolve the generating area 162 (made of quartz) to form a foreign material. In response thereto, the control module 180 may control the operation of the heating unit 163 (see FIG. 2) to prevent the formation of the liquid hydrogen oxide in the generating area 162. In detail, the heating unit 163 may be operated to provide the generating area 162 with an amount of heat that generates the gaseous hydrogen oxide without generating the liquid hydrogen oxide. The amount of heat may be determined by considering the temperature, pressure, and flow rate of the fluid during operation.

In order to generate the gaseous hydrogen oxide, the heating unit 163 may be operated for the set temperature to reach, for example, several hundred degrees Celsius. Referring to FIG. 4, the inventor confirmed that the amount of the dissolved silica is increased rapidly due to a temperature increase under a vapor pressure according to a water temperature, and then decreased rapidly as the temperature approaches a critical temperature (approximately 374° C.) and the silica dissolution no longer occurs. In order to prevent the silica dissolution, the heating unit 163 may be operated for the set temperature to be in a second temperature range different from a first temperature range, rather than in a temperature range (first temperature range) where the silica dissolution occurs. The second temperature range may have, for example, a temperature higher than that in the first temperature range. For example, the heating unit 163 may be operated to maintain the set temperature higher than the critical temperature. In this case, a temperature range higher than the critical temperature may be the second temperature range.

Referring further to FIGS. 1 and 2, the control module 180 may also control the fluid supply module 130 to regulate the supply amounts of the raw fluid and the protective gas. The pressure in the generating area 162 may be approximately the same as the processing pressure, and the generating area 162 may thus be exposed internally to the processing pressure and exposed externally to the protective pressure. Regulating the supply amount of the raw fluid may result in regulating the processing pressure. Regulating the supply amounts of the raw fluid and the protective gas may lead to adjusting a difference between the internal and external pressures in the generating chamber 161. The difference between the internal and external pressures may be maintained in the set relationship, thus preventing the generating chamber 161 from being damaged even at high pressure.

FIG. 5 is a cross-sectional view showing a generating module according to a modified example of FIG. 3.

Referring to this drawing, a generating module 160A is substantially the same as the generating module 160 in the previous embodiment, except that the generating module 160A further includes a casing chamber 165 and a heat blocking unit 167.

The casing chamber 165 may accommodate the generating chamber 161. In addition, the casing chamber 165 may also accommodate the heating unit 163. The casing chamber 165 may have a communication hole 166 for its communication with the protective area. Through the communication hole 166, the protective gas may enter the casing chamber 165, and the generating chamber 161 may be exposed externally to the protective pressure.

The heat blocking unit 167 is a component for blocking heat generated by the heating unit 163 from being transferred to the outside of the generating module 160A. The heat blocking unit 167 may also be installed in the casing chamber 165. The heat blocking unit 167 may have an insulating member and/or a cooling member. The insulating member may be a pad made of an insulating material, and coupled to an interior of the casing chamber 165. A refrigerant may flow in the cooling member.

In an alternative embodiment, the heat blocking unit 167 may surround the exterior of the heating unit 163. In that case, as in the previous embodiment, the casing chamber 165 may not be employed.

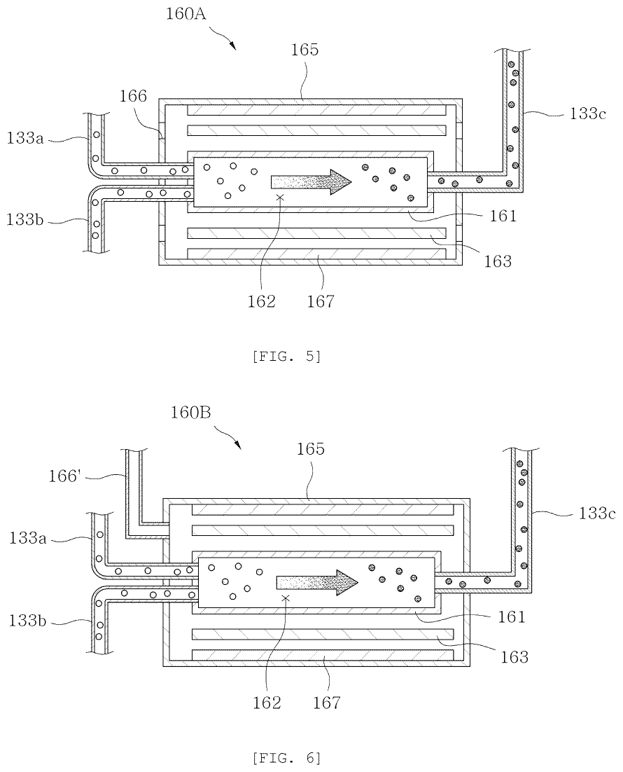

FIG. 6 is a cross-sectional view showing a generating module according to another modified example of FIG. 3.

Referring to this drawing, a generating module 160B is substantially the same as the generating module 160A in the previous modified example, except that generating module 160B has a communication line 166′instead of the communication hole 166.

In this modified example, the generating chamber 161 may be disposed outside the external chamber 120 (see FIG. 1). For the generating chamber 161 to be disposed in the atmosphere of the protective gas, the communicate line 166′may communicate the casing chamber 165 to the protective area.

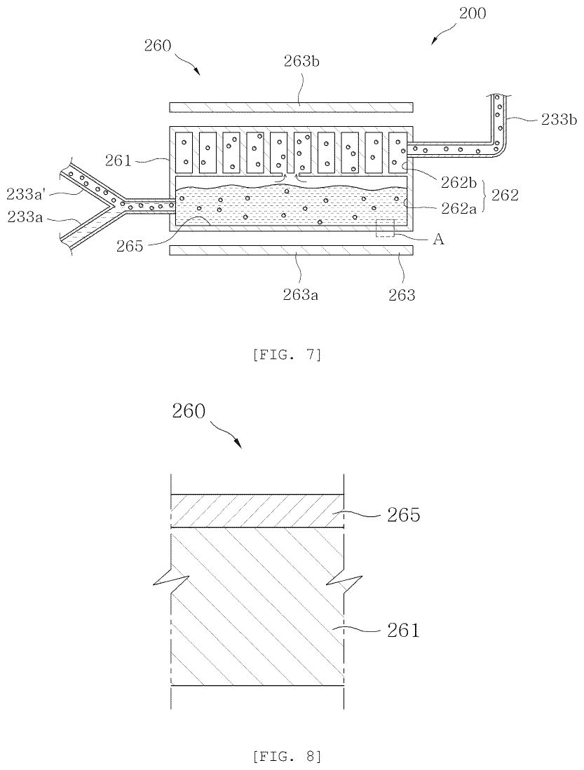

Hereinafter, a high pressure substrate processing apparatus 200 of another type is described with reference to FIGS. 7 and 8. FIG. 7 is a cross-sectional view showing a generating module according to another embodiment, and FIG. 8 is an enlarged cross-sectional view showing a portion of FIG. 7.

Referring to these drawings, the high pressure substrate processing apparatus 200 may have an internal chamber and an external chamber with substantially the same configuration as those in the high-pressure substrate processing apparatus 100 (see FIG. 1) in the previous embodiment. However, a generating module 260 may be different from the generating module 160 (see FIG. 3) in the previous embodiment.

The gaseous hydrogen oxide generating module 260 may include a generating chamber 261, a heating unit 263, and a reinforced coating layer 265.

The generating chamber 261 may be disposed in the atmosphere of the protective gas. In detail, the generating chamber 261 may be disposed in the protective area, and exposed externally to the protective pressure. The generating chamber 261 may be made of a metal, such as iron, chromium, nickel, or an alloy thereof. The generating chamber 261 may also be made of soluble quartz. In an alternative embodiment, the generating chamber 261 may be disposed in the atmosphere rather than the atmosphere of the protective gas, based on the pressure of the gaseous hydrogen oxide generated therein.

The generating chamber 261 may have a generating area 262 as its internal space. The liquid hydrogen oxide may be provided as the raw fluid to the generating area 262. In response to the liquid hydrogen oxide, the generating area 262 may be partitioned into a heating area 262a, which is a space where the liquid hydrogen oxide is fed and vaporized, and a superheating area 262b, which is a space where the gaseous hydrogen oxide is superheated. The superheating area 262b may communicate with the heating area 262a, and be disposed above the heating area 262a. The superheating area 262b may have, for example, a spiral-shaped flow path structure, and also cause the gaseous hydrogen oxide to be in a superheated state. The heating area 262a may be connected to a raw material line 233a communicating with the fluid supplier 131 (see FIG. 1), and the superheating area 262b may be connected to an input line 233b communicating with the processing area. A gas line 233a′ may be joined to the raw material line 233a, thus allowing a gas supplied along the gas line 233a′ to atomize the liquid hydrogen oxide. The gas may be the inert gas, for example, nitrogen gas.

The heating unit 263 may include a first heater 263a for heating and vaporizing the liquid hydrogen oxide in the heating area 262a. The first heater 263a may not output as much heat as the heating unit 163 (see FIG. 3) in the previous embodiment. The reason is that even if the generating chamber 261 is made of quartz and the liquid hydrogen oxide is present, the liquid hydrogen oxide is prevented from coming into direct contact with the generating chamber 261 due to the reinforced coating layer 265, thus preventing the dissolution of the generating chamber 261. The heating unit 263 may also include a second heater 263b for heating the gaseous hydrogen oxide in the superheating area 262b. The second heater 263b may be operated to superheat the gaseous hydrogen oxide. For this purpose, the second heater 263b may output an amount of heat different from that of the first heater 263a. Unlike the description above, the first heater 263a and the second heater 263b may be combined into one.

The reinforced coating layer 265 may be disposed in the generating chamber 261 defining the generating area 262. The reinforced coating layer 265 may block the liquid hydrogen oxide and/or the gaseous hydrogen oxide from coming into direct contact with the generating chamber 261. If the generating chamber 261 is made of quartz, the reinforced coating layer 265 may prevent quartz from being dissolved by the liquid hydrogen oxide. For this purpose, the reinforced coating layer 265 may be formed in the interior of the heating area 262a, and further, in the interior of the superheating area 262b.

The reinforced coating layer 265 may be made of a material having a different property from that of the generating chamber 261. For example, the reinforced coating layer 265 may be a plating layer. The plating layer may be made of, for example, gold, silver, nickel, or an alloy thereof. The gold may use high-purity gold (e.g., 99.9+%) to form a coating layer having excellent heat resistance and adhesion. The above nickel may use, for example, nickel sulfamate, which has a low content of a heavy metal and impurities to thus provide a highly reliable plating layer. The plating layer may be made, for example, by electroplating. The plating layer may not only block the direct contact between the liquid hydrogen oxide (or the gaseous hydrogen oxide) and the generating chamber 261, thereby preventing oxidation and corrosion occurring therebetween, but also prevent the plating layer itself from being oxidized or corroded by coming into contact with the liquid hydrogen oxide.

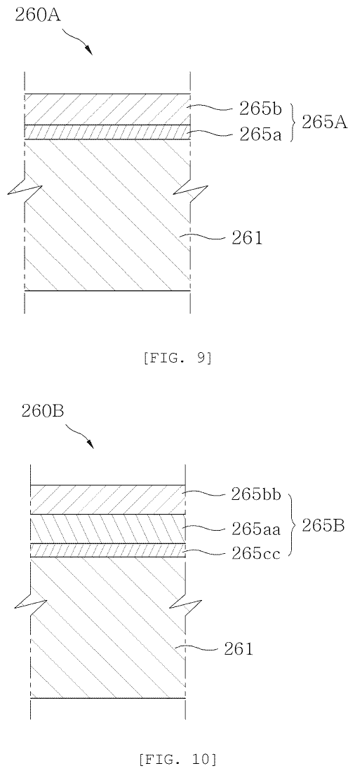

FIG. 9 is a cross-sectional view showing a generating module according to a modified example of FIG. 8.

Referring to this drawing, a gaseous hydrogen oxide generating module 260A may differ from the generating module 260 in the previous embodiment in that a plating layer 265A has a two-layer structure.

The plating layer 265A may have a first plating layer 265a and a second plating layer 265b. The first plating layer 265a may be disposed between the generating chamber 261 and the second plating layer 265b. The second plating layer 265b may be in direct contact with the liquid hydrogen oxide and/or the gaseous hydrogen oxide. The first plating layer 265a may be made of the same material as the second plating layer 265b. For example, both the first plating layer 265a and the second plating layer 265b may be plated with gold.

The first plating layer 265a may be formed using a strong acid gold plating solution. A strong acid component in the strong acid gold plating solution may remove a passive film formed in the interior of the generating chamber 261 and suppress the passive film that may be formed during plating. The second plating layer 265b may be formed using a high-purity plating solution (e.g., 99.9+%). The passive film may be formed in the interior using chromium, a component of a stainless steel, when the generating chamber 261 is made of stainless steel. For reference, before the first plating layer 265a is formed, the passive film may primarily be removed from the interior of the generating chamber 261 using hydrochloric acid or the like. In addition, the exterior of the second plating layer 265b may also be coated using an anti-tarnish.

The first plating layer 265a may be thinner than the second plating layer 265b. The first plating layer 265 a may be approximately 1/50 to 1/1,000 thinner than the second plating layer 265b. The strong acid gold plating solution may have a slow plating speed, and thus be used only to an extent necessary to remove the passive film.

FIG. 10 is a cross-sectional view showing a generating module according to another modified example of FIG. 8.

Referring to this drawing, a gaseous hydrogen oxide generating module 260B may differ from the generating module 260 in the previous embodiment in that a reinforced coating layer 265B has a three-layer structure.

In detail, the plating layer 265B may include a first plating layer 265aa, a second plating layer 265bb, and a third plating layer 265cc. If the second plating layer 265bb is disposed on the first plating layer 265aa, the third plating layer 265cc may be disposed between the first plating layer 265aa and the generating chamber 261. The second plating layer 265bb may be in direct contact with the liquid hydrogen oxide and/or the gaseous hydrogen oxide.

The first plating layer 265aa and the second plating layer 265bb may be made of different metals. For example, if the first plating layer 265aa is made of nickel (first metal), the second plating layer 265bb may be made of gold (second metal). The third plating layer 265cc may be made of the same metal (nickel) as the first plating layer 265aa.

The first plating layer 265aa may be made of a nickel sulfamate plating solution. The nickel sulfamate may have superior purity and heat resistance compared to other types of nickel. The second plating layer 265bb may be formed substantially the same as the second plating layer 265b (see FIG. 9) in the previous embodiment. The third plating layer 265cc may be substantially the same as the first plating layer 265a (see FIG. 9) in the previous embodiment, and made of a plating solution in which nickel is used instead of gold as a metal ion.

The third plating layer 265cc may be thinner than the first plating layer 265aa. For example, the third plating layer 265cc may be approximately 1/20 to 1/1,000 thinner than the first plating layer 265aa.

In an alternative embodiment, another reinforced coating layer similar to the reinforced coating layer 265 may also be formed in the internal chamber 110 (see FIG. 1). Another reinforced coating layer may also prevent the dissolution of the interior of the internal chamber 110 and the foreign material formation due to the oxidation/corrosion.

In an alternative embodiment, the reinforced coating layer may be a polymer layer. The polymer layer may include, for example, a silicone polymer. In detail, the polymer layer may include amorphous silicon oxide (a-SiO) and may withstand a high-temperature process. The polymer layer may also prevent the metal ion in the generating chamber from being captured in the gaseous hydrogen oxide. The polymer layer above may also protect the soluble material in the generating chamber from being dissolved.

Although this specification describes the high pressure substrate processing apparatus 100 as an example of the processing apparatus having dual chambers, the present disclosure is not limited thereto. The configurations of the generating module 160, 160A, 160B, 260, 260A, or 260B and the fluid supply module 130 or the control module 180 related thereto may also be applied to the processing apparatus having a single chamber. The single chamber may include one housing and one door. The substrate may be disposed in the chamber, and the processing gas for processing the substrate may also be supplied. The chamber may correspond to the internal chamber 110 (see FIG. 1) of the double chamber.

The configurations of the generating module 160, 160A, 160B, 260, 260A, or 260B and the fluid supply module 130 or the control module 180 related thereto may also be applied to a semi-dual chamber, which is an intermediate form between the double chamber and the single chamber. The semi-dual chamber may have two housings (internal housing and external housing) and one door. The two housings may be coupled to form a closed space (corresponding to the protective space) by their own shapes or by the intervention of a separate member. As in the previous embodiment, the substrate may be disposed in the processing area of the internal housing, the processing gas may be injected thereto, and the protective gas may be injected into the closed space. Unlike the previous embodiments, the door may not be completely protected by the protective gas and exposed externally. The door may correspond to the external door in the previous embodiment. The door may open and close the internal housing (and the external housing).

According to the high pressure substrate processing apparatus and the gaseous hydrogen oxide generating module according to the present disclosure configured as described above, the raw fluid may be supplied to the generating chamber of the generating module, which communicates with the internal chamber having the processing area while being accommodated in the protective area of the external chamber, and the heating unit, which heats the raw fluid under the control of the control module, may be operated to provide the generating area with the amount of heat that generates the gaseous hydrogen oxide from the raw fluid without generating the liquid hydrogen oxide, thus preventing the foreign material formed by dissolving the soluble material forming the generating chamber by the liquid hydrogen oxide generated from the raw fluid from being supplied to the processing area.

In addition, the reinforced coating layer may be disposed in the interior of the generating chamber of the generating module, thus preventing the raw fluid or the gaseous hydrogen oxide heated by the heating unit from coming into the direct contact with the generating chamber. Accordingly, it is possible to structurally prevent the foreign material formed by the oxidation, corrosion, dissolution, or the like caused by the direct contact of the raw fluid or the like with the generating chamber from being supplied to the processing area.

The specification exemplifies a batch type processing apparatus, and the present disclosure is not limited thereto. The present disclosure may also be applied to a single wafer type processing apparatus as it is.

What is claimed is:

1. A high pressure substrate processing apparatus comprising:
an internal chamber including a processing area accommodating a processing gas including gaseous hydrogen oxide and having a processing pressure higher than atmospheric pressure and accommodating a substrate to be processed using the processing gas;
a generating module including a generating chamber made of a soluble material and including a generating area accommodating a raw fluid while communicating with the processing area, and a heating unit configured to heat the raw fluid accommodated in the generating area to generate the gaseous hydrogen oxide; and
a control module configured to control the operation of the heating unit to provide the generating area with an amount of heat that generates the gaseous hydrogen oxide without generating liquid hydrogen oxide from the raw fluid.

2. The apparatus of claim 1, wherein the control module is configured to control the operation of the heating unit to allow a temperature in the generating area to be higher than a critical temperature of the gaseous hydrogen oxide.

3. The apparatus of claim 1, wherein the internal chamber further includes a wafer boat made of silicon carbide and configured to stack the substrate thereon.

4. The apparatus of claim 1, further comprising:
an external chamber including a protective area accommodating the internal chamber and a protective gas having a protective pressure set in relation to the processing pressure; and
a fluid supply module configured to supply the raw fluid to the generating area and the protective gas to the protective area,
wherein the control module is configured to control the operation of the fluid supply module to supply the raw fluid to the generating area to reach a pressure higher than the atmospheric pressure.

5. The apparatus of claim 4, wherein the generating chamber is disposed in an atmosphere of the protective gas, and
the control module is configured to control the operation of the fluid supply module to regulate supply amounts of the raw fluid and the protective gas for the processing pressure and the protective pressure to have a set relationship.

6. The apparatus of claim 5, wherein the generating chamber is disposed in the protective area.

7. The apparatus of claim 5, wherein the generating chamber is disposed outside the external chamber, and
the generating module further includes a casing chamber accommodating the generating chamber; and
a communication line communicating the casing chamber to the protective area.

8. The apparatus of claim 1, wherein the generating module further includes a casing chamber accommodating the generating chamber and the heating unit.

9. The apparatus of claim 8, further comprising an external chamber having a protective area accommodating the internal chamber and a protective gas having a protective pressure set in relation to the processing pressure,
wherein the casing chamber is configured to communicate with the protective area to expose the generating chamber to the protective pressure.

10. A high pressure substrate processing apparatus comprising:
an internal chamber including a processing area accommodating a processing gas including gaseous hydrogen oxide and having a processing pressure higher than atmospheric pressure and accommodating a substrate to be processed using the processing gas; and
a generating module including a generating chamber having a generating area accommodating a raw fluid while communicating with the processing area,
a reinforced coating layer disposed in an interior of the generating chamber defining the generating area, and
a heating unit configured to heat the raw fluid in contact with the reinforced coating layer to generate the gaseous hydrogen oxide.

11. The apparatus of claim 10, wherein the generating chamber is made of one of a metal and a soluble material, and
the reinforced coating layer includes a plating layer.

12. The apparatus of claim 11, wherein the plating layer includes
a first plating layer made of a first metal, and
a second plating layer made of a second metal, different from the first metal, and disposed on the first plating layer.

13. The apparatus of claim 10, further comprising an external chamber including a protective area accommodating the internal chamber and a protective gas having a protective pressure set in relation to the processing pressure,
wherein the generating chamber is disposed in the protective area to be exposed to the protective pressure.

14. The apparatus of claim 10, wherein the raw fluid includes liquid hydrogen oxide.

15. The apparatus of claim 10, wherein the generating chamber is made of one of a metal and a soluble material, and
the reinforced coating layer includes a polymer layer.

16. The apparatus of claim 15, wherein the polymer layer includes amorphous silicon oxide.

17. A gaseous hydrogen oxide generating module comprising:
a generating chamber including a generating area accommodating a raw fluid;
a reinforced coating layer disposed in an interior of the generating chamber defining the generating area; and
a heating unit configured to heat the raw fluid in contact with the reinforced coating layer to generate gaseous hydrogen oxide.

18. The module of claim 17, wherein the generating chamber is made of one of a metal and a soluble material, and
the reinforced coating layer includes a plating layer.

19. The module of claim 18, wherein the plating layer includes
a first plating layer made of a first metal, and
a second plating layer made of a second metal, different from the first metal, and disposed on the first plating layer.

20. The module of claim 17, wherein the generating chamber is made of one of a metal and a soluble material, and
the reinforced coating layer includes a polymer layer made of amorphous silicon oxide.
